(19) United States
(12) Patent Application Publication
(10) Pub. No.: US 2016/0265136 A1
(43) Pub. Date: Sep. 15, 2016

(54) FILM FORMING METHOD, FILM FORMING APPARATUS, AND STORAGE MEDIUM

(71) Applicant: TOKYO ELECTRON LIMITED, Tokyo (JP)

(72) Inventors: Kota UMEZAWA, Nirasaki City (JP); Yosuke WATANABE, Nirasaki City (JP)

(21) Appl. No.: 15/057,563

(22) Filed: Mar. 1, 2016

(30) Foreign Application Priority Data
Mar. 9, 2015 (JP) 2015-046020

(51) Int. Cl. C30B 25/16; C30B 29/40; C30B 25/18; C30B 29/06; C30B 25/10; C30B 25/12

(52) U.S. Cl. CPC C30B 25/16; C30B 25/10; C30B 25/12; C30B 25/186; C30B 29/06; C30B 29/403

(57) ABSTRACT

A film forming method for forming an aluminum nitride film on a substrate in which at least a surface portion is formed of a single crystal silicon through an epitaxial growth under a vacuum atmosphere, includes performing one or more times a cycle including a first process of supplying a raw material gas containing an aluminum compound to the substrate and a second process of supplying an ammonia gas to form a seed layer formed of an aluminum nitride by a reaction of the ammonia gas and the aluminum compound adsorbed onto the silicon substrate, and simultaneously supplying the raw material gas containing the aluminum compound and the ammonia gas to form an aluminum nitride film on the seed layer.

### CROSS-REFERENCE TO RELATED APPLICATION

This application claims the benefit of Japanese Patent Application No. 2015-046020, filed on Mar. 9, 2015, in the Japan Patent Office, the disclosure of which is incorporated herein in its entirety by reference.

### TECHNICAL FIELD

The present disclosure relates to a technique for forming an aluminum nitride (AlN) film on a substrate formed of silicon through epitaxial growth.

### BACKGROUND

As one of the uses of a film obtained by epitaxially growing AlN, using such a film as an intermediate layer when an epitaxial growth film of gallium nitride (GaN film) is formed on a substrate formed of a single crystal silicon (Si) has been considered. GaN is anticipated to be utilized as a power device and is also being spotlighted as a blue light emitting device in that it has a high dielectric breakdown voltage and a low conduction resistance. With respect to GaN, a technique that can grow a high quality crystal on a sapphire substrate has been developed; however, since the sapphire substrate is high in price, a technique for growing a high quality crystal even on an Si substrate is required. If a high quality GaN film could be formed on the Si substrate, an integrated circuit including a power device can be manufactured, thereby broadening the range of applications.

The high quality GaN crystal is obtained by forming an AlN epitaxial growth film (AlN film), which is an intermediate layer, on the Si substrate, and forming a GaN epitaxial growth film (GaN film) thereon. However, it is difficult to form the AlN film having a high quality crystal on the Si substrate. For example, an AlN film obtained at a process temperature of about 600 degrees C. through chemical vapor deposition (CVD) has poor crystallinity. Further, the crystallinity may be improved by increasing the process temperature to a high temperature such as, for example, 1000 degrees C. but a film stress is increased and thus an AlN film may be cracked if a film thickness is increased. Also, in order to form a high quality GaN film on the AlN film, the AlN film is required to have crystallinity with even higher quality.

Conventionally, a configuration in which a film formed of a Group-III element such as aluminum (Al), and nitrogen is grown on an Si substrate under a reduction atmosphere such as hydrogen (H₂) or ammonia (NH₃), with a seed material layer interposed therebetween, at a high temperature of 1000 degrees C. or more, and in which a 1 micrometer or less nitride is formed as the seed material layer by a deposition method using a high temperature CVD or a laser beam, is disclosed. However, it is not possible to obtain an AlN film having high quality without cracks in the above configuration.

### SUMMARY

Some embodiments of the present disclosure provide a technique capable of epitaxial-growing an AlN film, which is free from a possibility of the occurrence of cracks and which has a high quality crystal, on a substrate in which at least a surface portion is formed of a single crystal silicon.

According to one embodiment of the present disclosure, there is provided a film forming method for forming an aluminum nitride film on a substrate in which at least a surface portion is formed of a single crystal silicon through an epitaxial growth under a vacuum atmosphere, including: performing one or more times a cycle including a first process of supplying a raw material gas containing an aluminum compound to the substrate and a second process of supplying an ammonia gas to form a seed layer formed of an aluminum nitride by a reaction of the ammonia gas and the aluminum compound adsorbed onto the silicon substrate; and simultaneously supplying the raw material gas containing the aluminum compound and the ammonia gas to form the aluminum nitride film on the seed layer.

According to one embodiment of the present disclosure, there is provided a film forming apparatus for forming an aluminum nitride film on a substrate in which at least a surface portion is formed of a single crystal silicon through an epitaxial growth, including: a process vessel configured to form a vacuum atmosphere; a mounting table installed to mount the substrate within the process vessel; a heating part configured to heat the substrate mounted on the mounting table; and a control part configured to output a control signal such that a step of performing one or more times a cycle including a first process of supplying a raw material gas containing an aluminum compound to the substrate mounted on the mounting table and a second process of supplying an ammonia gas to form a seed layer formed of an aluminum nitride by a reaction of the ammonia gas and the aluminum compound adsorbed onto the silicon substrate; and a step of simultaneously supplying the raw material gas containing the aluminum compound and an ammonia gas to form the aluminum nitride film on the seed layer, are performed.

According to one embodiment of the present disclosure, there is provided a non-transitory computer readable storage medium storing a computer program to be used in a film forming apparatus having a process vessel in which a substrate is disposed and in which a vacuum atmosphere is formed, wherein the computer program is prepared to execute the film forming method described above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal side view of a film forming apparatus according to the present disclosure.

FIG. 2 is a timing chart illustrating timing at which each gas is supplied to a wafer by the film forming apparatus.

FIGS. 3A to 3E are longitudinal side views of a wafer.

FIG. 4 is a timing chart illustrating timing at which each gas is supplied to a wafer by the film forming apparatus.

FIG. 5 is a graph illustrating the results of a relationship between a film thickness and a full width at half maximum (FWHM) obtained from an evaluation test.

FIG. 6 is a graph illustrating X-ray diffraction spectrums obtained from evaluation tests.

FIG. 7 is a graph illustrating an intensity curve obtained from evaluation tests.

FIG. 8 is a graph illustrating X-ray diffraction spectrums obtained from evaluation tests.

FIG. 9 is a view illustrating images obtained from evaluation tests.

FIGS. 10A to 10C are views illustrating images obtained from evaluation tests.

FIGS. 11A and 11B are views illustrating images obtained from evaluation tests.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

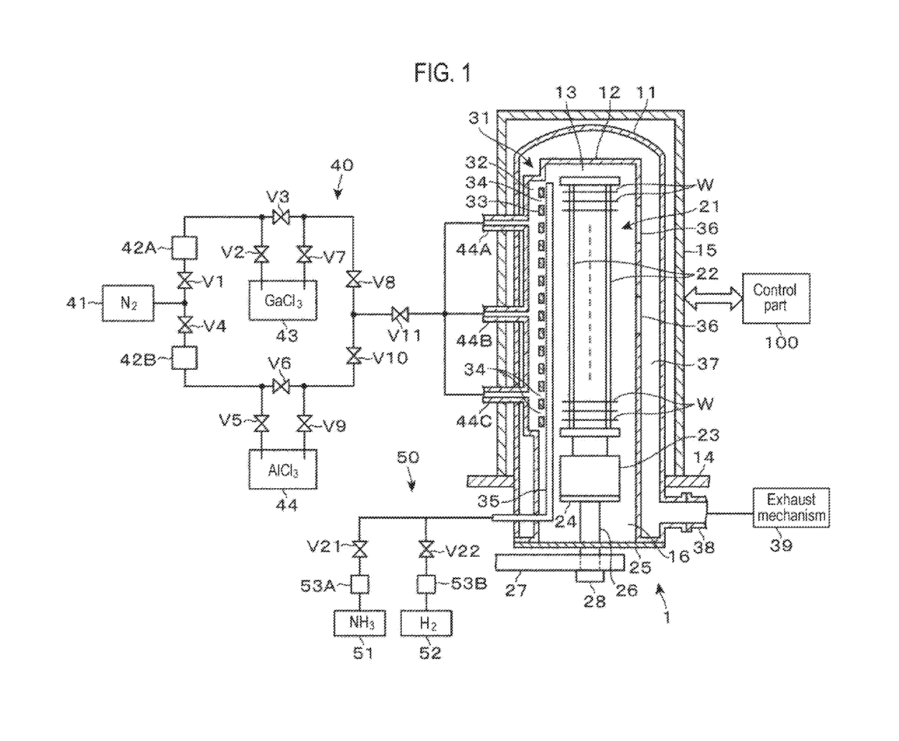

A film forming apparatus 1 according to an embodiment of the present disclosure will be described with reference to a schematic longitudinal side view of FIG. 1. The film forming apparatus 1 is configured to nitride a surface of a semiconductor wafer (hereinafter, referred to as a “wafer”) W as a substrate formed of a single crystal silicon under a vacuum atmosphere to form a silicon nitride (SiN) film, form an AlN film on the SiN film through epitaxial growth, and subsequently form a GaN film on the AlN film through epitaxial growth. As the wafer W, for example, a wafer whose surface is a crystal plane of Si expressed as (111) (hereinafter, referred to as an “Si (111) plane”) by Miller index is used. However, as can be seen from later evaluation tests, a wafer whose surface is a crystal plane of Si expressed as (100) (hereinafter, referred to as an “Si (100) plane”) by the Miller index may also be used.

In the film forming apparatus 1, a gas containing an aluminum trichloride (AlCl₃) is used to form the AlN film. The AlCl₃ is used to etch the wafer W composed of Si at a high temperature atmosphere, and thus, the SiN film is formed as a protective film for the AlCl₃ to prevent the AlCl₃ and Si on the surface of the wafer W from being in contact with each other. As described later, the SiN film is formed to have a film thickness that cannot hinder the epitaxial growth of the AlN film.

The film forming apparatus 1 is a vertical batch-type processing apparatus for forming films on a plurality of wafers W. In the drawing, reference numerals 11 and 12 denote an outer tube and an inner tube, respectively, which are formed of quartz and have a standing cylindrical shape with a ceiling. The inner tube 12 that forms a process vessel is installed inside the outer tube 11, and the interior of the inner tube 12 is configured as a process space 13 for processing the wafers W. In the drawing, reference numeral 14 denotes a base member having an opening, and the outer tube 11 and the inner tube 12 are inserted into the opening so as to be installed. In the drawing, reference numeral 15 denotes a heating part installed to surround the outer tube 11 on the base member 14 to heat the wafers W in the process space 13.

In the drawing, reference numeral 16 is an opening formed at a lower side of the process space 13, and a boat 21 serving as a substrate loading jig is loaded into or unloaded from the process space 13 through the opening 16. The boat 21 may be formed of quartz, have a plurality of posts 22 having recesses (not shown), and support the plurality of wafers W, for example, 50 to 150 wafers W, in a shelf shape in a vertical direction by virtue of the recesses. The boat 21 is placed on a table 24 forming a mounting table via a heat insulating member 23. The table 24 is supported on a rotary shaft 26 that passes through a lid part 25, and a lower end of the rotary shaft 26 is connected to a rotation mechanism 28 supported by an arm 27. During the film forming process, the rotary shaft 26 is rotated by the rotation mechanism 28 to rotate the boat 21. Further, the arm 27 is configured to ascend or descend, and as the arm 27 ascends or descends, the boat 21 and the lid part 25 ascend or descend to allow the boat 21 to be loaded into or unloaded from the process space 13 and to allow the opening 16 to be opened and closed by the lid part 25.

In the drawing, reference numeral 31 is a gas introduction part forming a portion of a sidewall of the inner tube 12, and the gas introduction part 31 is formed by a gas spreading space 32 and a spreading plate 33 formed along a height direction of the inner tube 12. A process gas supplied to the gas spreading space 32 is supplied to the process space 13 through a plurality of gas ejection holes 34 formed in a height direction of the spreading plate 33.

A pipe system 40 including valves V1 to V11 and a nitrogen (N₂) gas supply source 41 is connected to the gas introduction part 31. The N₂ gas supply source 41 is connected to one end of the valve V2 and one end of the valve V3 through the valve V1 and a mass flow controller (MFC) 42A in this order, and is connected to one end of the valve V5 and one end of the valve V6 through the valve V4 and an MFC 42B in this order. The other end of the valve V2 is connected to a constant temperature bath 43 that stores a solid gallium trichloride (GaCl₃). The other end of the valve V3 is connected to one ends of the valves V7 and V8, and the other end of the valve V7 is connected to the constant temperature bath 43.

The other end of the valve V5 is connected to a constant temperature bath 44 that stores a solid aluminum chloride (AlCl₃). The other end of the valve V6 is connected to one ends of the valves V9 and V10, and the other end of the valve V9 is connected to the constant temperature bath 44. The other ends of the valves V8 and V10 are connected to one end of the valve V11, and the other end of the valve V11 is connected to one ends of gas supply pipes 44A, 44B, and 44C. The other ends of the gas supply pipes 44A, 44B, and 44C are opened at different heights of the gas spreading space 32.

When the interiors of the constant temperature baths 43 and 44, are heated, sublimation occurs, and a GaCl₃ gas is generated from the solid GaCl₃ while an AlCl₃ gas is generated from the solid AlCl₃. The GaCl₃ gas and the AlCl₃ gas are supplied to the process space 13, together with the N₂ gas which is supplied as a carrier gas from the N₂ gas supply source 41 to the constant temperature baths 43 and 44. Also, as well as being supplied as the carrier gas to the process space 13, the N₂ gas of the N₂ gas supply source 41 is also supplied as a purge gas for purging a gas remaining in the process space 13. Specifically, when the GaCl₃ gas is introduced to the process space 13, the valves V1, V2, V7, V8, and V11 among the valve V1 to V11 of the pipe system 40 are opened, and the other valves are closed. When the AlCl₃ gas is introduced to the process space 13, the valves V4, V5, V9, V10, and V11, among the valves V1 to V11 of the pipe system 40, are opened and the other valves are closed. When the process space 13 is purged, at least one group of the valves V1, V3, V8, and V11 and the valves V4, V6, V10, and V11 is opened, and the valves V2, V5, V7, and V9 are closed.

Further, in the drawing, reference numeral 35 denotes a gas introduction pipe installed to extend toward an upper end portion from a lower end portion of the inner tube 12 in the vicinity of one side of a sidewall of the inner tube 12, and a plurality of gas ejection holes (not shown) for ejecting a gas toward the boat 21 is formed in a height direction. A pipe system 50 is connected to the gas introduction pipe 35, and includes an ammonia (NH₃) gas supply source 51 and a hydrogen (H₂) gas supply source 52 for supplying an NH₃ gas and an H₂ gas to the gas introduction pipe 35, respectively. The NH₃ gas supply source 51 is connected to the gas introduction pipe 35 through an MFC 53A and a valve V21 in this order, and the H₂ gas supply source 52 is connected to the gas introduction pipe 35 through an MFC 53B and a valve V22 in this order.

In the drawing, reference numeral 36 is an exhaust port installed on the other side of the sidewall of the inner tube 12, and the exhaust port is opened to an upper end, a middle end, and a lower end of the process space 13 and also communicates with an exhaust space 37 partitioned by the outer tube 11 and the inner tube 12. In the drawing, reference numeral 38 denotes an exhaust pipe with one end portion opened to the exhaust space 37. The other end of the exhaust pipe 38 is connected to an exhaust mechanism 39 configured by a vacuum pump or the like, and exhausts the process space 13 to a degree of vacuum required for the processing. Also, since the exhaust port 36, the gas introduction pipe 35, and the gas introduction part 31 are configured in this manner, each gas can be supplied to a surface of each of the wafers W loaded on the boat 21.

A control part 100 configured as a computer is connected to the film forming apparatus 1. A program is stored in the control part 100, and a control signal is output to each part of the film forming apparatus 1 by the program. Opening and closing of each valve, a supply amount of a gas by the MFC, an exhaust amount by the exhaust mechanism 39, a rotational operation of the boat 21 by the rotation mechanism 28, lifting of the arm 27, a temperature of the wafer W by the heating mechanism 15, and the like are controlled by the control signal. Since an operation of each part is controlled, each step is performed as described later to form a film on the wafer W. The above-described program is stored in the control part 100 in a state of being stored in a storage medium such as, for example, a hard disk, a flexible disk, a compact disk, a magnet optical disk (MO), or a memory card.

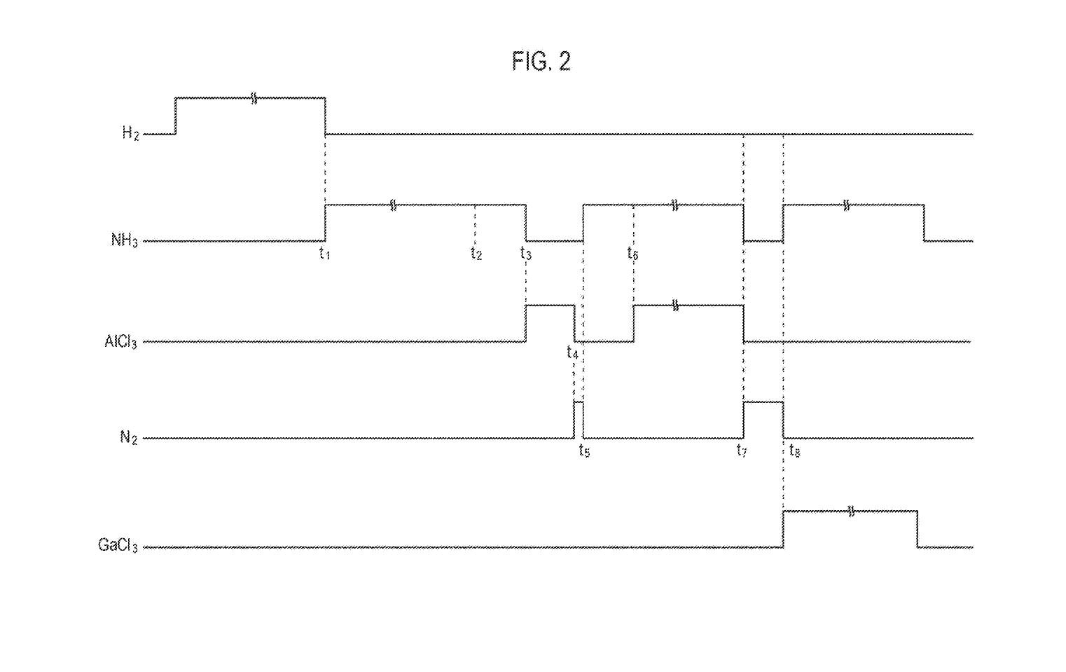

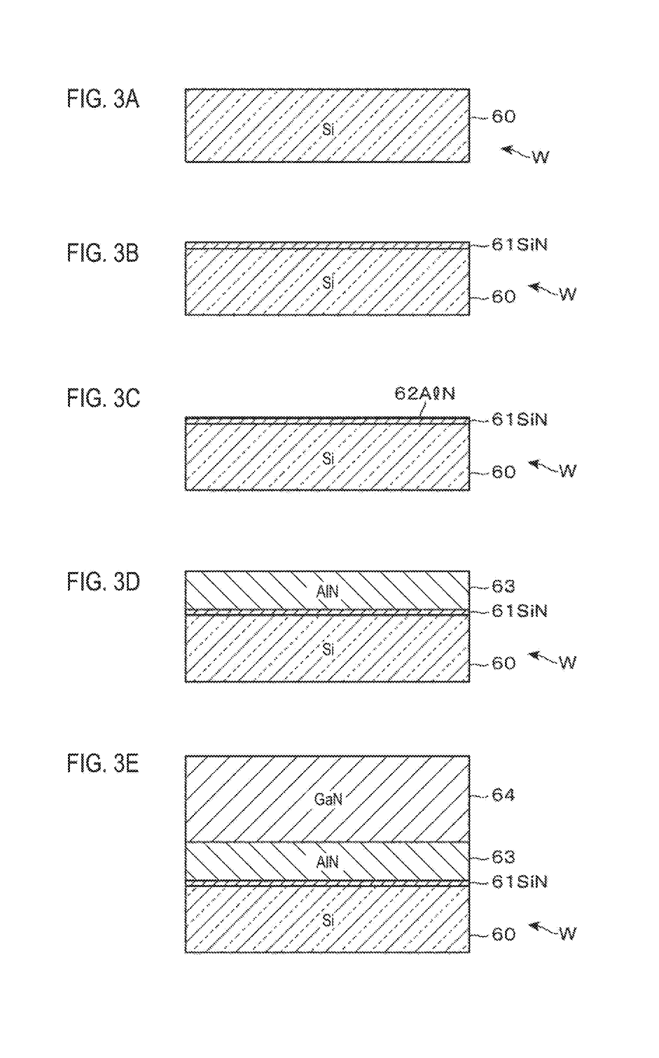

Next, a process flow performed by the film forming apparatus 1 will be described with reference to FIG. 2 as a timing chart illustrating timing for supply and stop of each gas to the process space 13 and FIGS. 3A to 3E as a longitudinal side view of the wafer W. In the chart, lines of respective gases are illustrated, a supply state of the gases to the process space 13 is illustrated depending on the height of a level of the lines. A high level indicates that the supply is performed, while a lower level means that the supply is stopped. Also, in the chart, N₂ denotes N₂ supplied as a purge gas, and in the chart, N₂ supplied as a carrier gas of an AlCl₃ gas and a GaCl₃ to the process space 13 is not illustrated.

First, on an outer side of the inner tube 12, after the plurality of wafers W described above are loaded on the boat 21, the lid part 25 is lifted to load the boat 21 into the process space 13, and at the same time the opening 16 of the inner tube 12 is closed by the lid part 25 to hermetically seal the process space 13. Thereafter, the process space 13 is exhausted to a vacuum atmosphere having a predetermined pressure, and the wafers W are heated to, for example, 900 to 1050 degrees C. The wafers W, heated to such a temperature, are processed in each of steps 1 to 9 shown below.

### (Step 1: Removal of Natural Oxide Film)

An H₂ gas is supplied to the process space 13, and a natural oxide film formed on a surface portion of the wafers W is reduced by the H₂ gas so as to be removed. FIG. 3A illustrates a wafer W after the removal of the natural oxide film, and an Si surface portion of the wafer W is denoted by 60.

### (Step 2: Formation of SiN Film)

At a time t1, which is, for example, 30 minutes after starting to supply an H₂ gas, the supply of the H₂ gas is stopped, a predetermined flow rate of an NH₃ gas starts to be supplied, and the process space 13 is exhausted to a pressure of 1000 Pa or less. In a state where the pressure of the process space 13 is adjusted in this manner, an outermost surface of the wafer W is nitrided by the NH₃ gas to form an SiN film 61 (FIG. 3B).

The SiN film 61 formed in this step S2 will be described in detail. In a follow-up step of step 2, an AlN film is formed on the SiN film 61 through the epitaxial growth as mentioned above. However, when a film thickness of the SiN film 61 is relatively large, the SiN film 61 becomes amorphous, and thus, in a follow-up step, the AlN film may be formed without being affected by a crystal axis of Si of the surface portion 60. That is, it is not possible to form an AlN film through the epitaxial growth.

Further, it has been considered that when a gas for forming a nitriding atmosphere is supplied to the wafer W before supplying a raw material gas for forming an AlN film the uppermost surface of the formed AlN film is configured by N atoms, among Al atoms and N atoms, to have the characteristics of N atoms. Also, it has been considered that, if the uppermost surface of the formed AlN film has the characteristics of N atoms, when a GaN film is formed on the AlN film through an epitaxial growth, the uppermost surface of the GaN film is also formed by N atoms. When the uppermost surface of the GaN film is formed by N atoms, the GaN film does not have the properties that may be applied for the uses as described in the Background section.

However, the inventors confirmed that, when a film thickness of the SiN film 61 is 4 nm or less, more preferably, 3 nm or less, an AlN film can be formed on the SiN film 61 through an epitaxial growth, that is, a crystal of AlN can be grown along a crystal axis of the Si surface portion 60, and the outermost surface of the AlN film has the characteristics of Al atoms. Thus, in this step 2, in order to form the SiN film 61 having a film thickness of 4 nm or less, the pressure of the process space 13 is set to be relatively low as described above and nitriding an outermost surface of the Si surface portion 60 is performed.

Further, for example, when the Si surface portion 60 is insufficiently nitrided, the film thicknesses of respective portions of the SiN film 61 have large variations. When an AlN film is formed in a follow-up step of step 2 in a state where the film thicknesses of the SiN film 61 have large variations, AlN crystals are grown individually from the respective portions of the SiN film 61, and thus, a size of a crystal grain of the AlN is reduced. As a result, a size of a crystal grain of GaN in the GaN film is also reduced. That is, the crystallinity of the GaN film is degraded. Thus, in this step 2, an NH₃ gas is supplied to the wafer W for a relatively long period of time.

In performing nitriding for a relatively long period of time, nitriding is performed from the uppermost surface of the Si surface portion 60 to a lower side of the Si surface portion 60, increasing a film thickness of the SiN film 61. In this case, since the pressure of the process space 13 is constantly kept at the relatively low range as described above, an increase in the film thickness is saturated with the lapse of time. That is, an increment of the film thickness is lowered. In a case in which this step 2 completes at a time t2 after the lapse of, for example, 30 minutes from the time t1, a value of {(d2−d1)/d1}×100%, which means an increase rate of the film thickness, is, for example, 3% or less, wherein a film thickness of the SiN film 61, 5 minutes ahead of the time t2, is d1 and a film thickness of the SiN film 61 at the time t2 is d2. Since the increase rate of the film thickness is lowered, the SiN film 61 having a film thickness with high uniformity is formed in each portion of the outermost surface of the Si surface portion 60, and when the step 2 is completed, a film thickness of the SiN film 61 can be suppressed to 4 nm or less as described above.

### (Step 3: Pressure Adjustment)

At the time t2, the pressure of the process space 13 is lowered to, for example, 30 to 133 Pa. This step S3 is performed to adjust the pressure of the process space 13 such that a gas can be uniformly supplied into the surface of each wafer W in each of follow-up steps. And then, the supply of the NH₃ gas to the process space 13 is stopped at a time t3 which is a time after the lapse of, for example, 1 minute from the time t2. Further, since this step 3 is performed for a relatively short period of time, an increase in a film thickness of the SiN film 61 is suppressed in step S3. Thus, even the film thickness of the SiN film 61 that is available after step 3 is completed falls within the range described in step 2.

### (Step 4: Supply of Raw Material Gas)

At the time t3, an AlCl₃ gas as a raw material gas for forming an AlN film starts to be supplied to the process space 13, and thus, the molecules of AlCl₃ forming the gas are adsorbed to a surface of the SiN film 61. At a time t4 after the lapse of, for example, 1 minute from the time t3, the supply of the AlCl₃ gas to the process space 13 is stopped.

### (Step 5: Purge)

At the time t4, an N₂ gas as a purge gas is supplied to the process space 13 and the AlCl₃ gas and the NH₃ gas remaining in the process space 13 are purged and removed from the process space 13. At a time t5 after the lapse of, for example, 10 seconds from the time t4, the supply of the N₂ gas is stopped.

### (Step 6: Formation of Seed Layer)

At the time t5, the NH₃ gas starts to be supplied to the process space 13, and thus, the pressure of the process space 13 ranges from, for example, 30 to 133 Pa. The molecules of AlCl₃ adsorbed to the wafer W in step 4 are nitrided by the NH₃ gas and a seed layer 62 formed of AlN is formed on a surface of the SiN film 61 (FIG. 3C). Since the seed layer 62 is formed by nitriding the AlCl₃ adsorbed to the SiN film 61, the seed layer 62 is formed as a dense crystal with high uniformity on the SiN film 61.

### (Step 7: Formation of AlN Film Through CVD)

At a time t6 after the lapse of, for example, 1 minute from the time t5, an AlCl₃ gas is supplied to the process space 13 in a state where the NH₃ gas continues to be supplied, making the pressure of the process space 13 range from, for example, 30 to 133 Pa. Also, on the seed layer 62, the NH₃ gas and the AlCl₃ gas are reacted to deposit AlN, and CVD is performed. Accordingly, the crystal of AlN is epitaxially grown on the seed layer 62, so that an AlN film 63 is formed by the seed layer 62 and the deposited AlN. Since the SiN film 61 is formed to have the above-described film thickness, the AlN film 63 is affected by a crystal axis of the Si surface portion 60 and thus a crystal axis of the AlN film 63 is aligned to the crystal axis of the Si surface portion 60. Since the seed layer 62 is dense and firm as described above, the AlN film 63 is grown without being cracked from a film stress of the AlN film 63 itself.

At a time t7 after the lapse of a predetermined time from the time t6, the supply of the NH₃ gas and the AlCl₃ gas to the process space 13 is stopped and the formation of the AlN film 3 is completed. FIG. 3D illustrates a wafer W that is available when the formation of the AlN film 63 is completed, and as mentioned above, the uppermost surface of the formed AlN film 63 has the characteristics of Al. Also, a film thickness of the AlN film 63 after the film formation is completed is a film thickness, for example, ranging from 200 to 300 nm, which sufficiently suppresses the warping of the wafer W due to a film stress of the GaN film to be formed in a follow-up step.

### (Step 8: Purge)

At the time t7, an N₂ gas is supplied and each gas remaining in the process space 13 is purged and removed from the process space 13. Thereafter, at a time t8, the supply of the N₂ gas is stopped.

### (Step 9: Formation of GaN Film)

At the time t8, a GaCl₃ gas and an NH₃ gas start to be supplied to the process space 13. GaN is deposited and epitaxially grown on the AlN film 63 through CVD using the GaCl₃ gas and the NH₃ gas and thus a GaN film 64 is formed.

For example, when a GaN film 64 having a film thickness ranging from, for example, 3 to 5 μm is formed (FIG. 3E), the supply of the GaCl₃ gas and the NH₃ gas is stopped. Thereafter, the lid part 25 descends to open the process space 13, and the boat 21 is unloaded from the process space 13.

According to the film forming apparatus 1, in forming the AlN film on the wafer W formed of a single crystal Si through epitaxial growth, the AlCl₃ gas as a raw material gas is supplied to the wafer W to allow the molecules of the AlCl₃ gas to be adsorbed, the NH₃ gas is subsequently supplied to form the seed layer 62 of AlN, and, thereafter, the AlCl₃ gas and the NH₃ gas are simultaneously supplied onto the seed layer 62. That is, after the seed layer 62 is formed through atomic layer deposition (ALD), a crystal is grown at a relatively high speed through CVD. Accordingly, the AlN film 63 is formed of a high quality crystal without cracks. Since cracks are not generated in the AlN film 63, a phenomenon that GaN is formed in cracks and the GaN reacts with Si forming the wafer W to form a metal compound, preventing reduction of yield of products. Further, since the AlN film 63 is formed of a high quality crystal, the GaN film 64 formed on the AlN film 63 through the epitaxial growth can also be formed of a high quality crystal to increase the quality of products.

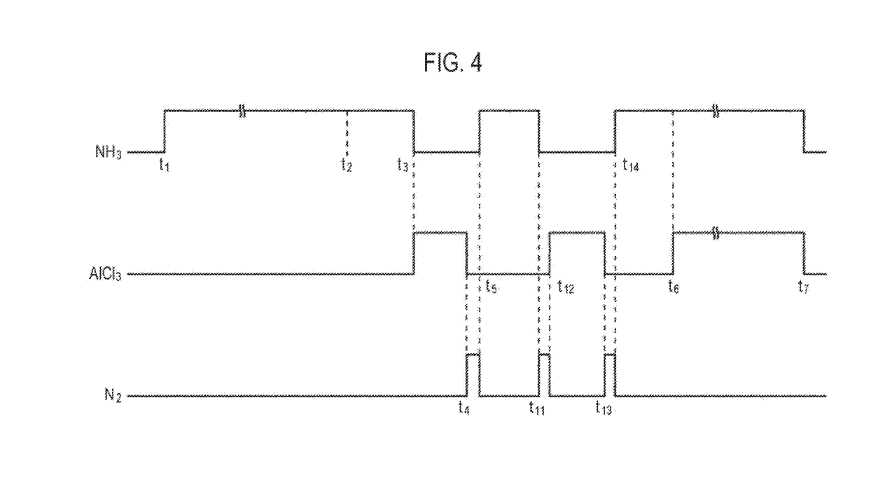

On the other hand, in the process flow of step 1 to step 9, in order to form the seed layer 62, a cycle of supplying the AlCl₃ gas, the N₂ gas (purge gas), and the NH₃ gas in this order is performed only once. However, the seed layer 62 may also be formed by performing the cycle a plurality of times. FIG. 4 is a chart illustrating timing of supply and stop of the AlCl₃ gas, the N₂ gas, and the NH₃ gas in case of forming the seed layer 62 by performing the cycle twice. Also, the supply and stop of the H₂ gas and the GaCl₃ gas are performed at the same timing as that of step 1 to step 9, and illustration thereof is omitted in the chart of FIG. 4.

Specifically, in the process illustrated in the chart of FIG. 4, each gas is supplied and stopped at times t1 to t5 like the chart illustrated in FIG. 2 and a seed layer 62 is formed on an SiN film 61. Subsequently, the supply of the NH₃ gas, which was started to be supplied at the time t5, is stopped and the N₂ gas is supplied (time t11) to purge the NH₃ gas within the process space 13. Thereafter, the supply of the N₂ gas is stopped and the AlCl₃ gas starts to be supplied (time t12) and the molecules of AlCl₃ are adsorbed onto the seed layer 62. And then, the supply of the AlCl₃ gas is stopped and the N₂ gas starts to be supplied (time t13) to purge the AlCl₃ gas within the process space 13, and subsequently, the NH₃ gas is supplied (time t14) to nitride the AlCl₃ molecules to form AlN, thereby increasing the thickness of the seed layer 62. Thereafter, each gas is supplied and stopped like the timing after the time t6 in the chart of FIG. 2 to form an AlN film 63 and a GaN film 64. Also, the cycle of the supply and stop of the AlCl₃ gas, the N₂ gas and the NH₃ to form the seed layer 62 may be performed three or more times.

However, in forming the AlN film 63, a raw material gas containing an aluminum compound is not limited to the AlCl₃ gas, and for example, a gas containing trimethylaluminum as an aluminum compound may also be used. Trimethylaluminum does not etch the wafer W formed of Si, and thus, when the AlN film 63 is formed by the trimethylaluminum, the seed layer 62 may be directly formed on the Si surface portion 60 without forming the SiN film 61.

Also, the CVD in step S7 is not limited to the configuration described above. For example, a configuration in which the NH₃ gas is supplied at a first flow rate to the process space 13, whereas the AlCl₃ gas is not supplied, and thereafter, the AlCl₃ gas is supplied simultaneously when or after the flow rate of the NH₃ gas is changed to a second flow rate lower than the first flow rate, whereby a film is formed through CVD by the AlCl₃ gas and the NH₃ gas remaining in the process space 13, may be performed. Changing to the second flow rate also includes changing the flow rate to 0, i.e., stopping the supply of the NH₃ gas. By performing CVD in this manner, the AlCl₃ gas is supplied to the process space 13 in a state where a partial pressure of the NH₃ gas in the process space 13 is lowered, compared with a period during which the NH₃ gas is supplied at the first flow rate, and thus, an excessive reaction between the NH₃ gas and the AlCl₃ gas in the outer side of the wafer W and in a peripheral portion of the wafer W is prevented, so that the AlCl₃ gas can be supplied with high uniformity into the surface of each wafer W to form a film. After the supply of the AlCl₃ gas, the process space 13 is purged with an N₂ gas. The AlN film 63 may also be formed by repeatedly performing one time or a plurality of times the cycle including the supply of the NH₃ gas, the change of the flow rate of the NH₃ gas, the supply of the AlCl₃ gas, and the purging of each gas.

Hereinafter, evaluation tests performed according to the present disclosure will be described.

### (Evaluation Test 1)

In an evaluation test 1-1, a film forming process was performed on a wafer W having a surface including an Si (111) plane according to the above steps 1 to 7 to form an SiN film 61 and an AlN film 63. The film forming process was performed a plurality of times such that the AlN film 63 having a different film thickness in every process was formed. Also, in an evaluation test 1-2, after the steps S1 to S5 were performed, the seed layer 62 was not formed in step 6 and the AlN film 63 was formed through CVD of step 7. In the evaluation test 1-2, a flow rate of the NH₃ gas was 1 slm and pressure of the process space 13 was 0.3 Torr (40 Pa) in step 7. Also, in step 7 of the evaluation test 1-2, an H₂ gas was supplied at 2 slm in order to adjust a partial pressure of each gas in the process space 13. Also, in the evaluation test 1-2, the film forming process was performed a plurality of times to form the AlN film 63 having a different film thickness, like the evaluation test 1-1.

Each wafer W subjected to the film forming process in the evaluation test 1-1 and the evaluation test 1-2 was measured by an X-ray rocking curve method to obtain a full width at half maximum (FWHM) of a rocking curve of a crystal plane (hereinafter, referred to as an “AlN (002) plane”) of the AlN film 63 expressed as (002) by Miller indices. As a value of the measured FWHM is smaller, the crystal has higher crystallinity, that is, the crystal has a high quality. Further, a surface image of the AlN film 63 of the wafer W that underwent the film forming process in the evaluation test 1-1 and the evaluation test 1-2 was obtained by scanning electron microscope (SEM) and observed. Also, other crystal planes of AlN, other than the AlN (002) plane, will be expressed using the Miller indices, like the AlN (002) plane.

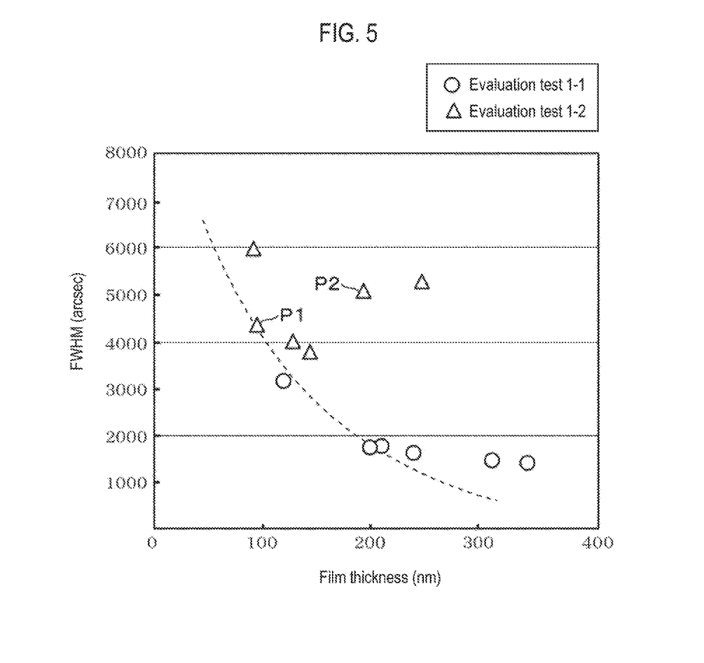

The graph of FIG. 5 illustrates the result of the evaluation test 1, in which the horizontal axis and the vertical axis represent the film thickness (unit: nm) of the AlN film 63 and the FWHM (unit: arcsec) of the graph, respectively. In the graph of FIG. 5, circular plots indicate the result of the evaluation test 1-1, and triangular plots indicate the result of the evaluation test 1-2. In addition, the dotted line of the graph is an approximate curve obtained from the FWHM of the AlN (002) plane of the AlN film obtained by performing measurement through the X-ray rocking curve method, for a plurality of samples formed with the AlN film having a different film thickness. The crystallinity of the AlN film of the samples is high, and thus, the FWHM is reduced as a film thickness of the AlN film is increased in the approximate curve. Since the approximate curve is obtained in this way, the plots having high crystallinity with respect to the AlN film formed in the evaluation test 1-1 and the evaluation test 1-2 are positioned in the approximate curve or close to the approximate curve.

As can be obvious from the graph, the plot group of the evaluation test 1-1 tends to be closer to the approximate curve, compared with the plot group of the evaluation test 1-2. More specifically, an FWHM of plots having a film thickness of 200 nm or greater, among the plots of the evaluation test 1-2, is greater than an FWHM represented in the approximate curve and has a large gap from the FWHM represented in the approximate curve. However, the plots of the evaluation test 1-1 are positioned in the approximate cure or near the approximate curve even though a film thickness is 200 nm or greater.

Also, no crack was observed from an image obtained from the AlN film 63 of a plot (indicated by P 1) having a film thickness of 90 nm and positioned in the approximate curve, among the plots of the evaluation test 1-2. However, cracks were observed from an image obtained from the AlN film 63 of a plot (indicated by P2) having a film thickness of 180 nm and having a considerable gap from the approximate curve, among the plots of the evaluation test 1-2. Also, Rms granularity of the AlN film 63 of the plot P1 was 0.73 nm and that of the AlN film 63 of the plot P2 was 2.45. Regarding this, no crack was observed from an SEM image obtained from the AlN film 63 of each plot having a film thickness of 200 nm or greater in the evaluation test 1-1.

From the above results, it can be seen that the crystallinity of the AlN film 63 is degraded due to the occurrence of crack. Also, it can be seen that, since the AlN film 63 is formed through CVD after the formation of the seed layer 62, the crystallinity of the AlN film 63 can be increased, compared with a case in which the AlN film 63 is formed through CVD without forming the seed layer 62, and also, even though a film thickness of the AlN film 63 is relatively increased, the occurrence of crack can be prevented. Thus, the effect of the present disclosure was confirmed from the evaluation test 1.

### (Evaluation Test 2)

In an evaluation test 2-1, a film forming process was performed on a wafer W having a surface of a silicon (111) plane in the same manner as that of the evaluation test 1-1 to form an AlN film 63 having a film thickness of 250 nm. Also, in an evaluation test 2-2, a film forming process was performed on a wafer W having a silicon (111) plane in the same manner as that of the embodiment 1 of the evaluation test 1 to form an AlN film 63 having a film thickness of 250 nm. And then, an X-ray diffraction was performed on the wafer W of the evaluation test 2-1 and on the wafer W of the evaluation test 2-2.

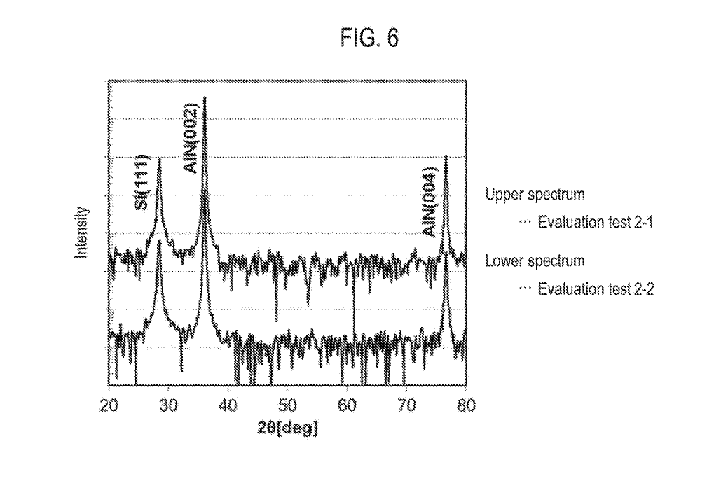

FIG. 6 is a graph illustrating spectrums obtained from the X-ray diffraction, in which the upper end side and the lower end side represent spectrums of the wafer W of the evaluation tests 2-1 and 2-2, respectively. The vertical axis of the graph represents intensity (arbitrary unit) and the horizontal axis represents a diffraction angle (unit: degree). In the respective spectrums of the evaluation tests 2-1 and 2-2, peaks representing the Si (111) plane, the AlN (002) plane, and the AlN (004) plane are checked. It is preferred that the AlN film 63 preferably has AlN (002) plane and AlN (004) plane in crystal orientation, and thus, it can be seen from the respective spectrums that the crystals of AlN having desirable orientation were formed in both of the evaluation tests 2-1 and 2-2.

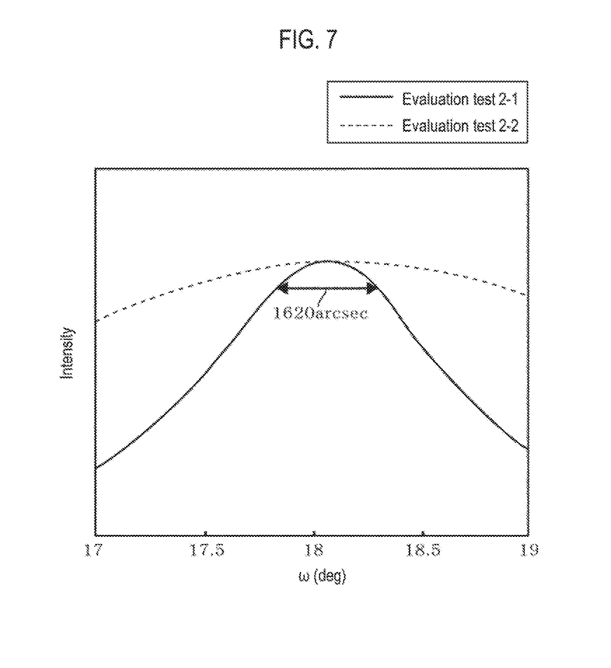

Subsequently, measurement was performed on the AlN (002) planes of the AlN films 63 of the evaluation tests 2-1 and 2-2 according to an X-ray rocking curve method to obtain rocking curves as illustrated in the graph of FIG. 7. In FIG. 7, the rocking curves of the evaluation tests 2-1 and 2-2 are represented by the solid line and the dotted line, respectively. The vertical axis of the graph represents intensity (arbitrary unit) and the horizontal axis represents angle (unit: degree). With respect to the rocking curves, FWHMs were obtained and compared, and the result was that the FWHM of the evaluation test 2-1 was smaller to be 1620 arcsec. Thus, it was also shown in the evaluation test 2 that the crystallinity of the AlN film 63 can be increased when the AlN film 63 was formed through CVD after the formation of the seed layer 62, like the evaluation test 1. Also, from the evaluation test 2, it was confirmed that the wafer W having an Si (111) plane can be used in the present disclosure.

### (Evaluation Test 3)

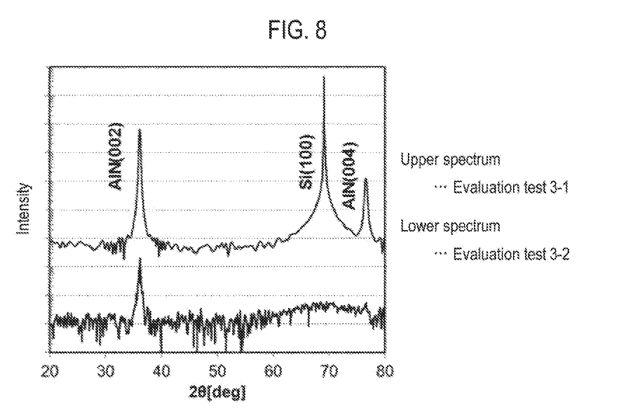

In evaluation tests 3-1 and 3-2, a film forming process was performed on a wafer W having a surface of an Si (100) plane in the same manner as that of the evaluation tests 2-1 and 2-2 to form an AlN film 63 having a film thickness of 250 nm, and an X-ray diffraction was performed. The graph of FIG. 8 is spectrums obtained by the X-ray diffraction, in which the upper end side and the lower end side represent spectrums of the wafer W of the evaluation tests 3-1 and 3-2, respectively. In the spectrum of the evaluation test 3-1, relatively high peaks indicating an AlN (002) plane and an AlN (004) plane appear in addition to the peak indicating an Si (100) plane. However, in the spectrum of the evaluation test 3-2, a relative high peak indicating the AlN (004) plane is not observed. Also, a peak, which is not observed in the spectrum of the evaluation test 3-1, appears in degrees from 37 to 40, and the appearance of the peak indicates that a crystal having different orientation from that of the AlN (002) plane was formed.

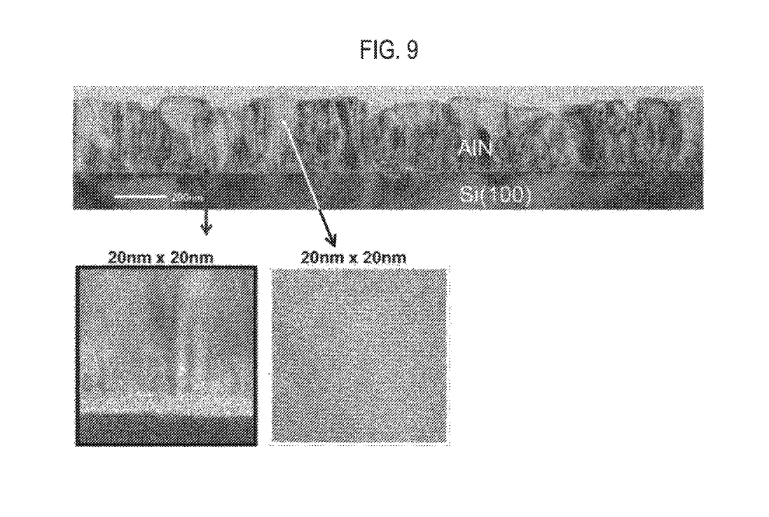

Regarding the wafer W on which the AlN film 63 was formed in the evaluation test 3-1, an image of a longitudinal side was obtained through a transmission electron microscope (TEM). FIG. 9 shows the obtained image. In the drawing, rectangular regions, which are 20 μm by 20 μm in length and width, of the longitudinal sides of a portion of the AlN film 63 are illustrated under magnification at the ends of the arrows. It was confirmed from the images that the orientation of the AlN (002) plane was formed as seen in the spectrums of FIG. 8.

The results shows that, when the AlN film 63 is formed through CVD without formation of the seed layer 62, it is not possible to form the AlN film on the wafer W having the Si (100) plane such that the AlN film has effective orientation of a crystal, but the AlN film 63 can be formed to have effective orientation of a crystal even on the wafer W having the Si (100) plane by using the method of forming the AlN film 63 through CVD according to the present disclosure after formation of the seed layer 62. Thus, according to the present disclosure, it was confirmed that a degree of freedom of the wafer W which is used can be increased.

Further, measurement was also performed on the AlN (002) plane of the wafer W of the evaluation tests 3-1 and 3-2 according to the X-ray rocking curve method to obtain rocking curves and FWHMs of the curves. The results showed that the FWHM of the rocking curve of the evaluation test 3-1 was smaller than that of the rocking curve of the evaluation test 3-2. Thus, the effect of the present disclosure also appears from the evaluation test 3. Also from the evaluation test 3, it was apparent that the crystallinity of the AlN film 63 can be increased by forming the AlN film 63 through CVD after the formation of the seed layer 62, like the evaluation tests 1 and 2.

### (Evaluation Test 4)

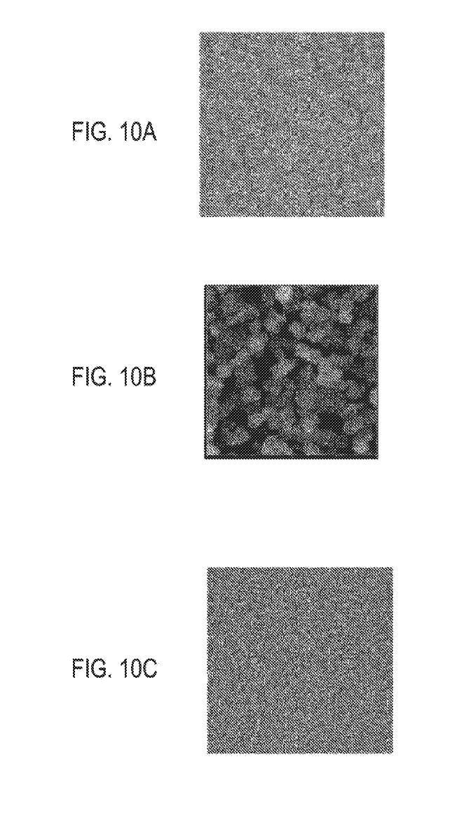

In evaluation tests 4-1 and 4-2, a film forming process was performed on a wafer W having an Si (100) plane in the same manner as that of the evaluation tests 3-1 and 3-2 to form an AlN film 63 having a film thickness of 200 nm. And then, an image of a surface of the AlN film 63 was obtained by an SEM. FIGS. 10A and 10B show images obtained from the AlN film 63 of the evaluation test 4-1. FIG. 10A is an image of a quadrangular region, which is 4 μm by 4 μm in length and width, and FIG. 10B is an image of a rectangular region, which is 2 μm by 2 μm in length and width. Also, in the image of FIG. 10B, the Rms granularity of the AlN film 63 was 15.6 nm FIG. 10C is an image obtained from the AlN film 63 of the evaluation test 4-2, which is a rectangular region that is 4 μm by 4 μm in length and width. It was confirmed from the images that the AlN film 63 of the evaluation test 4-1 in which the seed layer 62 was formed has higher orientation of crystal than that of the AlN film 63 of the evaluation test 4-2 in which the seed layer 62 was not formed. Thus, the effect of the present disclosure was also obtained from the evaluation test 4.

### (Evaluation Test 5)

In an evaluation test 5-1, an AlN film 63 was formed on a wafer W having a surface as an Si (111) plane according to steps 1 to 8 of the foregoing embodiment. In the evaluation test 5-1, an Si surface portion 60 was nitrided for 30 minutes in step 2 in the same manner as that of the embodiment. In an evaluation test 5-2, an AlN film 63 was formed in the same manner as that of the evaluation test 5-1, but in the evaluation test 5-2, an Si surface portion 60 was nitrided for one minute in step 2. Thereafter, images of longitudinal sides of the wafer W that underwent the film forming process were obtained by a TEM.

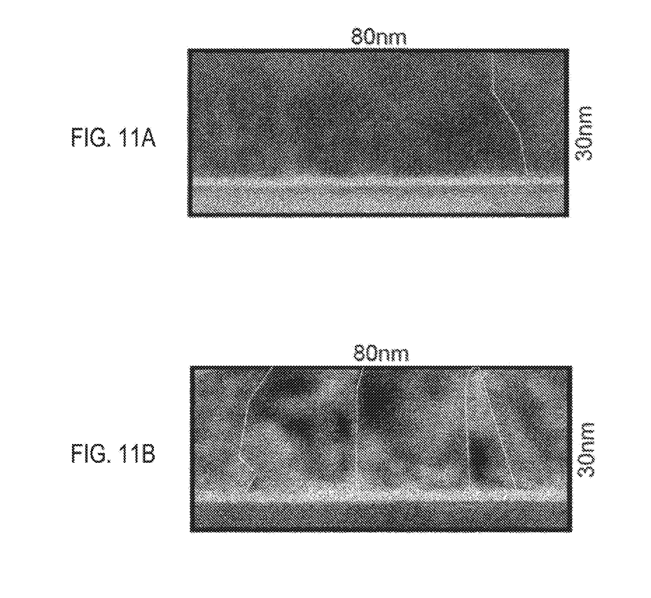

FIGS. 11A and 11B show images of the wafers W of the evaluation tests 5-1 and 5-2, respectively. In the drawings, the lines indicating crystal grain boundaries of the AlN films 63 are shown in the obtained images. It can be seen from the images that the surface smoothness of the SiN film 61 in the evaluation test 5-1 was higher than that of the SiN film 61 of the evaluation test 5-2. Also, the crystal grain boundary in the evaluation test 5-1 was smaller than that of the evaluation test 5-2. That is, it was confirmed that, in the evaluation test 5-1, the size of the crystal grain of AlN was greater and the crystallinity was higher. As described in the embodiment, it can be seen from the result of the evaluation test 5 that performing nitriding for a relatively longer period of time to restrain variations in film thickness of the SiN film 61 in step 2 is effective to increase the crystallinity of the AlN film 63.

According to the present disclosure in some embodiments, in forming an AlN film on a substrate having at least a surface portion formed of a single crystal Si through an epitaxial growth, a cycle of supplying a raw material gas containing an aluminum compound to the substrate and subsequently supplying an NH₃ gas is performed one or more times, and thereafter, the raw material gas and the NH₃ gas are simultaneously supplied to epitaxial-grow AlN. Since the cycle is performed one or more times, the high quality AlN film is formed on the substrate and the AlN film is formed on the AlN film through CVD, cracks do not occur and the AlN film having a high quality crystal can be obtained as can also be seen from the experimental examples.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method for forming an aluminum nitride film on a substrate in which at least a surface portion is formed of a single crystal silicon through an epitaxial growth under a vacuum atmosphere, comprising:
performing one or more times a cycle including a first process of supplying a raw material gas containing an aluminum compound to the substrate and a second process of supplying an ammonia gas to form a seed layer formed of an aluminum nitride by a reaction of the ammonia gas and the aluminum compound adsorbed onto the silicon substrate; and
simultaneously supplying the raw material gas containing the aluminum compound and the ammonia gas to form an aluminum nitride film on the seed layer.

2. The method of claim 1, wherein purging an atmosphere under which the substrate is processed with a purge gas is performed between the first process and the second process.

3. The method of claim 1, wherein the raw material gas is an aluminum halide, and
wherein the method comprises, before starting the cycle, forming a protective film formed of a silicon nitride film having a film thickness of 4 nm or less on a surface of the substrate by supplying the ammonia gas to the substrate.

4. The method of claim 3, wherein the forming the protective film is performed at a process pressure of 1000 Pa or less.

5. The method of claim 4, wherein, in the forming the protective film, when a film thickness that is available, 5 minutes before the forming the protective film is stopped, is d1 and a film thickness that is available when the forming the protective film is stopped is d2, a value of {(d2−d1)/d1}×100%, which is an increase rate of the film thickness, is 3% or less, when viewed in a relationship between the film thickness and a film formation time of the silicon nitride film.

6. A non-transitory computer readable storage medium storing a computer program to be used in a film forming apparatus having a process vessel in which a substrate is disposed and in which a vacuum atmosphere is formed,
wherein the computer program is prepared to execute the film forming method of claim 1.

7. A film forming apparatus for forming an aluminum nitride film on a substrate in which at least a surface portion is formed of a single crystal silicon through an epitaxial growth, comprising:
a process vessel configured to form a vacuum atmosphere;
a mounting table installed to mount the substrate within the process vessel;
a heating part configured to heat the substrate mounted on the mounting table; and
a control part configured to output a control signal such that a step of performing one or more times a cycle including a first process of supplying a raw material gas containing an aluminum compound to the substrate mounted on the mounting table and a second process of supplying an ammonia gas to form a seed layer formed of an aluminum nitride by a reaction of the ammonia gas and the aluminum compound adsorbed onto the silicon substrate; and a step of simultaneously supplying the raw material gas containing the aluminum compound and the ammonia gas to form an aluminum nitride film on the seed layer, are performed.

8. The apparatus of claim 7, wherein the raw material gas is an aluminum halide, and
wherein the control part is configured to output the control signal such that, before starting the cycle, a silicon nitride film having a film thickness of 4 nm is formed on a surface of the substrate by setting a process pressure to be 1000 Pa or less and supplying the ammonia gas to the substrate.
